(19) United States
(12) Patent Application Publication
(10) Pub. No.: US 2025/0185443 A1
(43) Pub. Date: Jun. 5, 2025

(54) AGRIPHOTOVOLTAIC TANDEM SELECTIVE SPECTRAL ABSORBANCE AND TRANSMITTANCE SOLAR SYSTEM

(71) Applicant: Doral Energy-Tech Ventures L.P., Ramat Gan (IL)

(72) Inventors: Shai GARTY, Rehovot (IL); Yuval SHAMIR, Kibbutz Hagoshrim (IL); Axel BENICHOU, Ramat Gan (IL); Michael DOVRAT, Modiin (IL)

(21) Appl. No.: 18/525,592

(22) Filed: Nov. 30, 2023

(51) Int. Cl. H10K 30/57; A01G 13/02; H02S 20/20; H10K 30/80

(52) U.S. Cl. CPC H10K 30/57; A01G 13/21; H02S 20/20; H10K 30/80

(57) ABSTRACT

The present invention discloses mean and methods for using of a suspended solar cell system in agriphotovoltaic culture of plants, wherein said use comprising steps of providing a “tandem” selective spectral absorbance and transmittance system whose total transmittance is tailored to match said plants' required absorption (light intensity vs wavelength); providing said system with a base-area A_{Tandem}; and culturing said plants in an area A_{Surface} below said a base-area A_{Tandem}; said A_{Tandem}≥f×A_{Surface}; f ranges between 0.51 to 1.00. The present invention discloses agriphotovoltaic “tandem” selective spectral absorbance and transmittance system useful for culture of plants.

### FIELD OF THE INVENTION

The present invention pertains both to agriphotovoltaic use of a tandem selective spectral absorbance and transmittance solar cell and to elevated agriphotovoltaic systems covering at least 95% of the field below.

### BACKGROUND OF THE INVENTION

Agrivoltaics or agriphotovoltaics is co-developing the same area of land for both solar photovoltaic power as well as for agriculture. The coexistence of solar panels and crops implies a sharing of light between these two types of production. Producing meaningful amounts of electric power using photovoltaic solar cells requires a relatively large amount of area space, i.e., about 1.6 square meter produces 250 Watt at peak hours, or 2 kWh per day in a typical sunny day. In order to accumulate meaningful amounts of energy, one requires vast amounts of land.

In recent years, some owners of farmland have started to utilize their land to generate electric energy by installing large amounts of photovoltaic panels due to the financial gains presented, often at the expense of the original agricultural use of the land. Others have found a way for the co-existence of photovoltaic modules alongside the original crops by physically dividing the space—putting photovoltaic modules on roofs of farm buildings, and in between rows of plants, in order to take advantage of the space not used for agricultural purposes. Usually, in order that the crops themselves get their required dose of sunlight energy, the use of photovoltaic panels on the same space is limited to 30-50%.

Photosynthesis is the main biological process by which plants convert the sunlight into a useful form of chemical energy which can later be utilized within the plant. Plants have specific requirements regarding the daily dose of light received, as well as the wavelengths of the light they require for a healthy plant life. Plants use different parts of the sunlight spectrum and require different light intensities during the various stages of plant growth, as can be seen in FIG. 1. McCree's work in the 1970's, see K. J. McCree, The action spectrum, absorptance and quantum yield of photo-synthesis in crop plants. Agric Meteorol, Vol. 9, pp. 191-216 (1972), has established the efficiency in which plants utilize different parts of the spectrum and established the “McCree curve” which shows the internal quantum efficiency used by plants, in the wavelength at the range of 300 to 800 nm.

Whereas the photosynthetically active region (PAR) of sunlight is defined in the range of 400-700 nm, plants also utilize some light outside of this range (below 400 nm and above 700 nm). In addition, although chlorophyll, the main pigment involved in photosynthesis, has its absorption peaks in the red and blue parts of the spectrum, plants are able to absorb and also require the entire spectrum (including yellow and green light) for other processes.

Plants also have very particular requirements for light dose in various stages of growth. However, most plants do not require the full intensity of sunlight even during their most demanding growth stages. In fact, plants have internal mechanisms to protect itself from higher than required light intensities (causing light stress). The required photosynthetic photon flux density (PPFD— the amount of PAR photons reaching the plant per area and time) is 50-60% of the sun's intensity.

The objective of the present invention is a selective spectral absorbance and transmittance solar cell, which can be deployed over the entire area used for agricultural purposes while maintaining the ideal light spectrum and intensity required for the plants. As can be seen in the FIG. 2, comparing the sun's spectrum with McCree's curve, also considering PPFD, or intensity, by the difference between those curves, it is evident that there are significant parts of the spectrum (both in wavelength and intensity) that can be utilized for photovoltaic energy conversion, without preventing any of the light required for healthy plant growth.

The following FIG. 3, presents the same data in a slightly different manner. It shows the spectral transmittance required for the plants (in red) and the supplemental spectral absorptance (plus any reflectance) that the photovoltaic cells must exhibit (in green) in order to allow the required amount of sunlight to reach the plants underneath.

We exploit two types of solar cells exhibiting specific tailored spectral tunability—namely quantum dots and perovskite solar cells, and fabricate a tandem solar cell with several layers whose total absorptance (and reflectance) matches the required one presented in the FIG. 3. This tunability can be achieved by composition selection and the production process conditions; the type and size of quantum dots govern their absorption spectrum, the additives used in perovskites based solar cells achieve the same goal.

Furthermore, this tunability can be exploited to match not only the general McCree curve, but a curve which is tailored specifically to match a particular plant type's spectral requirement in order to optimize both energy use and plant growth simultaneously.

Another issue that is important to address is the toxicity of the raw materials used to fabricate the solar cells. Whether it is the end-of-life (dismounting, recycling) of the modules or during normal operation, it is very desirable to use raw materials that are non-toxic to biological lifeforms (both flora and fauna, land or marine), such as lead (Pb), Arsenic (As) etc. which are known to be poisonous and dangerous even at very low levels of exposure.

### BRIEF DESCRIPTION OF THE FIGURES

The patent or application file contains at least one drawing executed in color. Copies of this patent or patent application publication with color drawing(s) will be provided by the Office upon request and payment of the necessary fee.

The accompanying drawings, which are included to provide a further understanding of the present disclosure and constitute a part of this specification, illustrate certain embodiments of the present disclosure and, together with the written description, serve to explain various aspects of the present disclosure; wherein the figures illustrate as follows:

FIG. 1. McCree curve for the relative energy used by the plants over the wavelength;

FIG. 2. Photons flux arriving from the sun (in blue) vs. the plants yield photons flux (in red), over the wavelength spectrum of 300-1200 nm;

FIG. 3. Spectral transmittance required for the plants (in red) and the supplemental spectral absorptance that the photovoltaic cells must exhibit (in green);

FIG. 4. Synthesis of colloidal quantum dots, and its composition-dependent engineered band gap;

FIG. 5. A “tandem” selective spectral absorbance and transmittance solar cell and system thereof according to one embodiment of the present invention; and

FIG. 6. A “tandem” selective spectral absorbance and transmittance solar cell and system thereof according to another embodiment of the present invention;

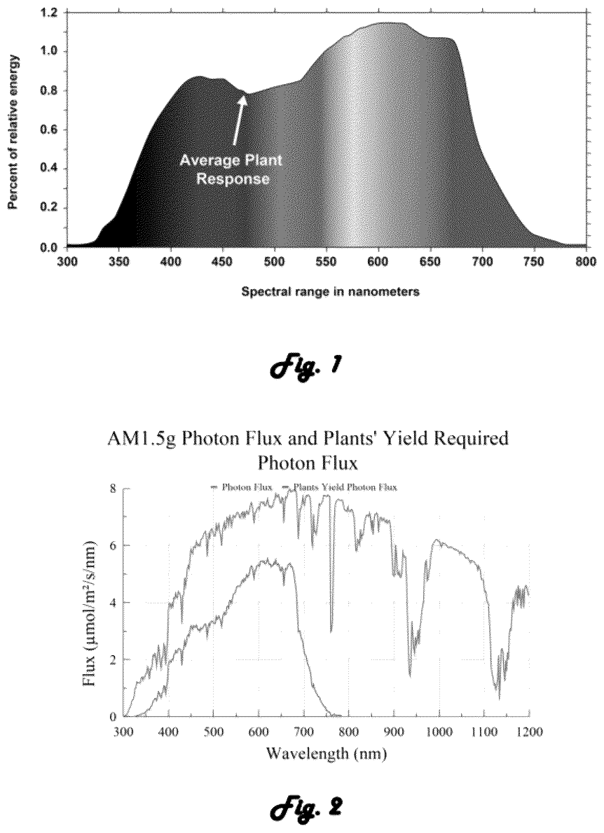

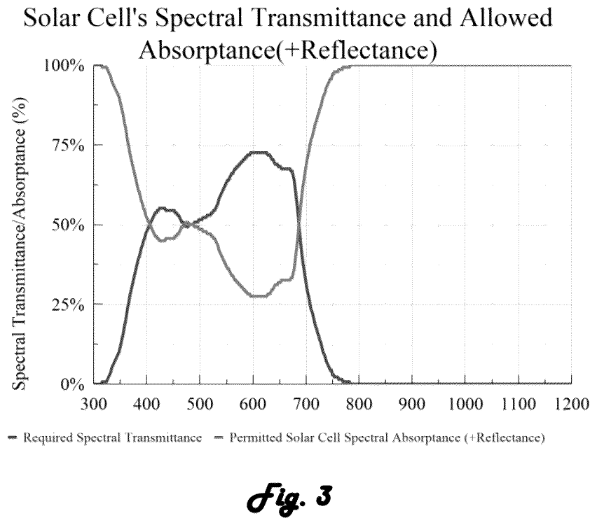

### SUMMARY OF THE INVENTION

It is hence one object of the present invention to disclose use of a suspended solar cell system in agriphotovoltaic culture of plants, wherein said use comprising steps of providing a “tandem” selective spectral absorbance and transmittance system whose total transmittance is tailored to match said plants' required absorption (light intensity vs wavelength); providing said system with a base-area A_{Tandem}; and culturing said plants in an area A_{Surface} below said a base-area A_{Tandem}; said A_{Tandem}≥f×A_{Surface}; f ranges between 0.51 to 1.00.

Another object of the present invention is to disclose use of a suspended solar cell system in agriphotovoltaic culture of plants as defined above, wherein said solar cell system comprising a plurality of n layers of absorbing materials, n is integer being equal or greater than 1, whose total transmittance is tailored to match plants' required absorption (light intensity vs wavelength); further comprising mechanically separate selective spectral absorbance and transmittance thin film solar cells, whose electrical contacts are connected outside the cells' active area, monolithically integrated; wherein said solar cell light absorption in different wavelengths is tuned by using different semiconducting quantum-dots and/or different wavelength-tunable perovskite-based absorption layers; wherein said solar cell transmittance in different wavelength is determined by one or more members of a group consisting of (a) type of layers used, absorbing different wavelengths; (b) concentration of absorption centers (which affects the transmittance of light in the wavelength region absorbed by said absorption centers); and (c) thickness of the wavelength-specific active layer in the cell (determining the amount of light absorbed/transmitted vs other layers in the solar cell

Another object of the present invention is to disclose use of a suspended solar cell system in agriphotovoltaic culture of plants as defined in any of the above, wherein absorptance/transmittance properties of the solar cell are tailored not to transmittance curve general to all plants (the McCree curve) and a “synthetic” solar spectrum, but to a specific type of plant, at a specific physical latitude (sun orientation and intensity).

Another object of the present invention is to disclose use of a suspended solar cell system in agriphotovoltaic culture of plants as defined in any of the above, wherein materials comprising the solar cells are non-toxic to biological lifeforms, e.g., not containing heavy-metals, including those selected from a group consisting of lead (Pb), chrome (Cr), and Antimony (Sb).

Another object of the present invention is to disclose a suspended solar cell system useful for agriphotovoltaic culture of plants, wherein at least one portion of said solar cell system is a “tandem” selective spectral absorbance and transmittance system whose total transmittance is tailored to match said plants' required absorption (light intensity vs wavelength); the base-area of “tandem” selective spectral absorbance and transmittance system is A_{Tandem}; plants are culturable in an area A_{Surface} below said a base-area A_{Tandem}; said A_{Tandem}≥f×A_{Surface}; f ranges between 0.51 to 1.00.

Another object of the present invention is to disclose a suspended solar cell system useful for agriphotovoltaic culture of plants as defined above, wherein said solar cell system comprising a plurality of n layers of absorbing materials, n is integer being equal or greater than 1, whose total transmittance is tailored to match plants' required absorption (light intensity vs wavelength); further comprising mechanically separate selective spectral absorbance and transmittance thin film solar cells, whose electrical contacts are connected outside the cells' active area, monolithically integrated; wherein said solar cell light absorption in different wavelengths is tuned by using different semiconducting quantum-dots and/or different wavelength-tunable perovskite-based absorption layers; wherein said solar cell transmittance in different wavelength is determined by one or more members of a group consisting of (a) type of layers used, absorbing different wavelengths; (b) concentration of absorption centers (which affects the transmittance of light in the wavelength region absorbed by said absorption centers); and (c) thickness of the wavelength-specific active layer in the cell (determining the amount of light absorbed/transmitted vs other layers in the solar cell

Another object of the present invention is to disclose a suspended solar cell system useful for agriphotovoltaic culture of plants as defined in any of the above, wherein said solar cell wherein absorptance/transmittance properties of the solar cell are tailored not to transmittance curve general to all plants (the McCree curve) and a “synthetic” solar spectrum, but to a specific type of plant, at a specific physical latitude (sun orientation and intensity).

Another object of the present invention is to disclose a suspended solar cell system useful for agriphotovoltaic culture of plants as defined in any of the above, wherein materials comprising the solar cells are non-toxic to biological lifeforms, e.g., not containing heavy-metals, including those selected from a group consisting of lead (Pb), chrome (Cr), and Antimony (Sb).

### DETAILED DESCRIPTION OF THE PREFERRED EMBODIMENTS

Reference will now be made in detail to the various embodiments of the disclosure, one or more examples of which are illustrated in the figures. Within the following description of the drawings, the same reference numbers refer to same components. Generally, only the differences with respect to individual embodiments are described. Each example is provided by way of explanation of the disclosure and is not meant as a limitation of the disclosure. Further, features illustrated or described as part of one embodiment can be used on or in conjunction with other embodiments to yield yet a further embodiment. It is intended that the description includes such modifications and variations.

The term “solar cell module” in the present invention means a structural body comprising a plurality of solar cells (photovoltaic elements) electrically connected with each other in series while being sealed by means of a sealing material including an organic sealing resin. The term “solar cell module string” means a string comprising a plurality of solar cell modules arranged while being electrically connected with each other in series. As used in some of the embodiments herein, the term “solar cell” refers to the component for converting solar energy into electrical energy. In some embodiments, the terms “solar cell” and “battery sheet” can be used interchangeably. In some embodiments, a solar cell is silicon-based. In some embodiments, a solar cell does not comprise silicon and instead comprises glass or plastic sheet.

The term “at least partially transparent” refers to a solar cell that its transparency in a relevant ranges of wavelength ranges from about 5% to about 95% of the irradiated intensity. By way of example, the solar cell is transparent and is configured or translucent to transmit at least about 50%, or alternatively, at least 90%, or alternatively, at least 99% of the intensity, or alternatively, more than about 5%, or alternatively, more than 10%, or alternatively, more than 25% or alternatively, more than about 50%.

The term “about” refers hereinafter to a value being greater or smaller than up to 20% of the defined measure.

In some embodiments the solar cell comprises composite solar materials, e.g., copper indium gallium selenide (CIGS), cadmium telluride (CdTe), gallium arsenide (GaAs). In some embodiments, a solar cell can comprise organic solar materials or polymer solar materials. In some embodiments, a solar cell can be a dye-sensitized solar cell. continuing goal is to reduce the cost, size and/or complexity of solar devices, while maintaining, and preferably improving, robustness of the devices. Accordingly, it is desired to develop improved solar cells. Although the term “solar cell” refers to “solar” and thus implies that it is configured to work with sunlight, the term “solar cell” is utilized in the art to refer generically to devices which convert electromagnetic radiation from any source (sunlight or otherwise) to electrical energy. The term “solar cell” is utilized in some of the embodiments herein to refer to devices which convert electromagnetic radiation from any source into electrical energy, and is to be understood to be broad enough to include devices which convert light from regions of the electromagnetic spectrum outside of the wavelengths primarily associated with sunlight.

The term “solution” is used herein to refer to a mixture of a solid and a liquid. While in some embodiments, the term “solution” refers to a mixture wherein the solid is dissolved in the liquid, this term also encompasses a colloidal solution, or dispersion solution, where the solid particles are dispersed in the liquid.

### Perovskite Solar Cell Parts

As defined in US20200127204A1 and elsewhere, the term “perovskite,” as used herein, refers to a material having the general structural formula QZX3, wherein Q and Z are cations of different sizes and X is an anion. The skilled person will also appreciate a perovskite material could be represented by the formula [Q][Z][X]₃, wherein Q is at least one cation, Z is at least one cation and X is at least one anion. In some embodiments, the “Q” component of the material is selected from methylammonium CH₃NH₃(MA), formamidinum CH(NH₂)₂(FA), n-butylammonium, tetra-butylammonium C₄H₉NH₃ (BA), and combinations thereof, the Z component is selected from a transition metal such as Pb, Sn, Cs, or combinations thereof; and the X component is selected from a halogen such as I, Cl, Br, and variants thereof. Additionally, or alternatively, in the case of an organometal halide, the Q site refers to an organic group, Z represents a metal such as lead or cesium, and X is a halide group such as iodide, chloride, fluoride, or bromide. For example, suitable perovskite materials include, but are not limited to, materials selected from the group consisting of: MAPbI₃, MAPbBr₃, MAPbIₓBr₃₋ₓ, MAPbIₓCl₃₋ₓ, FAPbI₃, FAPbBr₃, FAPbIxBr₃₋ₓ, FAPbIₓCl₃₋ₓ, BAPbI₃, BAPbBr₃, BAPbIₓBr₃₋ₓ, BAPbIₓCl₃₋ₓ, MASnI₃, MASnBr₃, MASnIₓBr₃₋ₓ, FASnI₃, FASnBr₃, FASnIₓBr₃₋ₓ, FASnIₓCl₃₋ₓ, BASnI₃, BASnBr₃, BASnIₓBr₃₋ₓ, BASnIₓCl₃₋ₓ, FA_{y}Cs_{z}MA_{1-y-x}(I₁₋ₓBrₓ)₃, and combinations and mixtures thereof. In some examples, the perovskite layer comprises CH₃NH₃PbI₃(MAPbI₃). In some examples, the perovskite layer is prepared by a solution processing technique, such as spin coating or a roll-to-roll printing process. The perovskite layers can be derived from a perovskite material as described herein.

The perovskite layer can, for example, have an average thickness of 300 nm or more; e.g., 325 nm or more, 350 nm or more, 375 nm or more, 400 nm or more, 425 nm or more, 450 nm or more, 475 nm or more, 500 nm or more, 550 nm or more, 600 nm or more, 650 nm or more, 700 nm or more, 750 nm or more, 800 nm or more, 850 nm or more, or 900 nm or more. In some examples, the perovskite layer can have an average thickness of 1000 nm or less; e.g., 950 nm or less, 900 nm or less, 850 nm or less, 800 nm or less, 750 nm or less, 700 nm or less, 650 nm or less, 600 nm or less, 550 nm or less, 500 nm or less, 475 nm or less, 450 nm or less, 425 nm or less, 400 nm or less, 375 nm or less, or 350 nm or less. The average thickness of the perovskite layer can range from any of the minimum values described above to any of the maximum values described above For example, the perovskite layer can have an average thickness of from 300 nm to 1000 nm; e.g., from 300 nm to 650 nm from 650 nm to 1000 nm, from 300 nm to 400 nm, from 400 nm to 500 nm, from 500 nm to 600 nm, from 600 nm to 700 nm, from 700 nm to 800 nm, from 800 nm to 900 nm, from 900 nm to 1000 nm, from 300 nm to 500 nm, or from 400 nm to 900 nm. The thickness of the perovskite layer can be determined by cross-sectional scanning electron microscopy.

### Quantum Dots (QD) Solar Cells

The term “quantum dots” is used herein to refer to a semiconductor crystal, which is typically several nanometers in size, such as from about 1 nm to about 100 nm.

Composition of QD suitable for agriculture The bandgaps of quantum dots are tunable across a wide range of energy levels and can be controlled by the quantum dot size. This is in contrast to bulk materials, where the bandgap is fixed by the choice of material composition. This property makes quantum dots more attractive for multi junction solar cells, where a variety of energy levels can convert more power from the solar spectrum. Half of all the solar energy reaching the Earth is in the infrared, most of it in the near infrared region. With a quantum dot solar cell, IR-sensitive materials are just as easy to use as any other, opening the possibility of capturing much more energy cost-effectively. QD can be simply deposited on a transparent substrate through spin coating. In large-scale production, the deposition could be achieved by spray-on or roll-printing systems, which are relatively low-cost processes. The QD composition is non-toxic for humans, animals, and plants, in case of panel failure, or for panel preparation or recycling purposes. The QDs are composed of nano-crystals of heavy metal dispersed within a transparent panel of glass or plastic.

According to one set of embodiments, the composition of heavy metal is non-toxic and does not comprise cadmium, mercury, arsenic, or lead. A Cadmium free QD composition, for example, may comprise doped ZnS/ZnSe, graphene, silicon, and CsSnI₃.

According to yet another set of embodiments, QD solution may comprise QD that are coated with octadecene, oleylamine, oleic acid, and/or surface-active agent/ligand(s).

According to another set of embodiments, QD solution may comprise liquid carrier such as ethanol, toluene, and hexane.

According to another set of embodiments, QD solution may comprise Poly(vinyl alcohol) (e.g., PVA, Mw 100,000) which is useful as a coating agent for indium tinoxide (ITO) substrates and providing a planar texture.

According to another set of embodiments, core composition comprises a nano-crystal which comprises, e.g., zinc, aluminum, gallium, indium, thallium, silver, gold, copper, cobalt, iron, nickel, telluride, antimony, silicon, manganese, indium, selenium, sulfur and any combination thereof, including, inter alia, zinc sulfide, zinc oxide, zinc selenide, zinc telluride, aluminum nitride, aluminum sulfide, aluminum phosphide, aluminum antimonide, aluminum indium nitride, indium aluminum phosphide, aluminum gallium phosphide, aluminum indium gallium nitride, gallium nitride, gallium phosphide, gallium antimonide, indium nitride, indium phosphide, indium antimonide, indium gallium nitride, indium gallium phosphide, thallium nitride, thallium phosphide, thallium antimonide, silver indium selenide sulfide, silver indium selenide, gold indium selenide sulfide, gold indium sulfide, copper aluminum selenide sulfide, copper gallium selenide sulfide, copper aluminum selenide, copper gallium selenide, copper indium selenide sulfide and any derivative and combination thereof.

According to another set of embodiments, QD solution may comprise a core and a shell as presented in the art, see e.g., US20190051779A1 Colorless luminescent solar concentrators using colloidal semiconductor nanocrystals.

According to another set of embodiments, a shell material is used to enhance core's stability, to enable good dispersion on a matrix, and to improve the photo-luminescent intensity of the core nano-crystal.

According to another set of embodiments, QDs are characterized by their tunable band gap properties. Such a tuning is provided useful by altering QD's particle size, and tuning metal chalcogenide composition by e.g., engineering particles' stoichiometry.

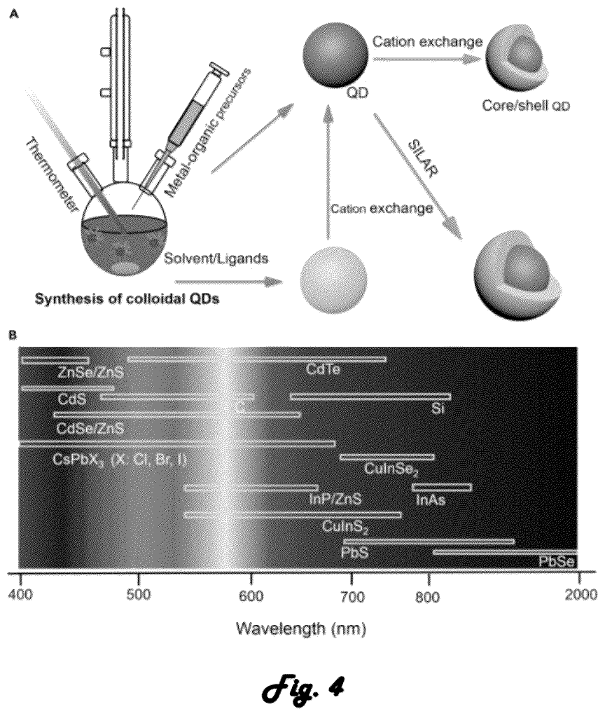

QDs synthesis and defining their emission range It is in the scope of the invention wherein QDs are prepared and structured by any commercially available means and methods, including utilizing either or both the cation exchange and SILAR synthetic approaches. As for the emission range for representative QDs, FIG. 4. Schematically depicts the synthesis of colloidal quantum dots, and its composition-dependent engineered band gap. For both the issues of synthesis and defining emission range, reference is made to applicable methods disclosed by Adegoke, O., Park, E. Size-confined fixed-composition, and composition-dependent engineered band gap alloying induces different internal structures in L-cysteine-capped alloyed quaternary CdZnTeS quantum dots. Sci Rep 6, 27288 (2016); and Haiguang Zhao, Federico Rosei, Colloidal Quantum Dots for Solar Technologies, Chem, 3, 2, 2017, Pages 229-258.

It is well in the scope of the invention wherein the aforesaid technology is applied in building elevated structures; e.g., suspended construction's or otherwise assemblies that are provided above surface area; containing the compositions defined hereafter. The elevated structures are provided useful for installing photovoltaic cells, solar panels, and any other means to harvest sun electromagnetic radiation and heat thereof. Those selective spectral absorbance and transmittance panels provide both efficient and land-saving agri-voltaic usages as defined below: Under and below the elevated structures there are lower surface(s) utilizable to other sun (light and warmth)—requiring uses, including human and animal habitats, agriculture, e.g., growing field crops, land vegetation, horticulture, aquaculture etc.

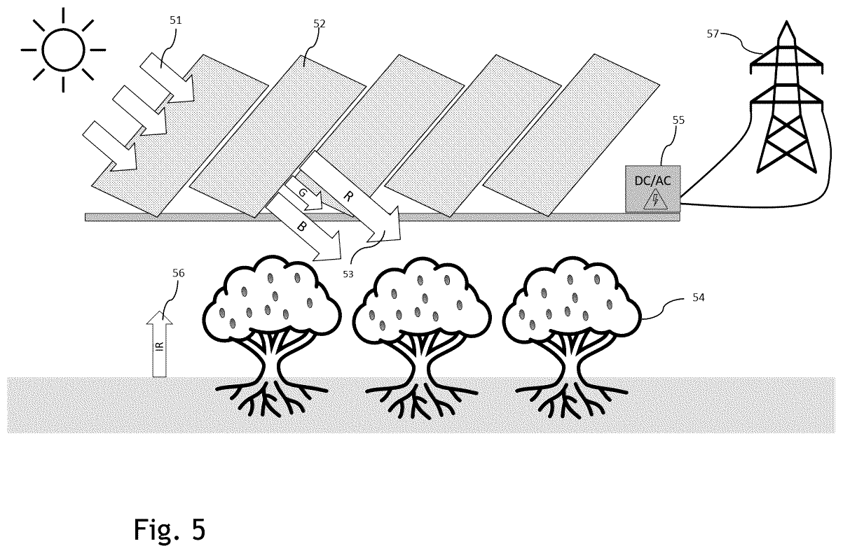

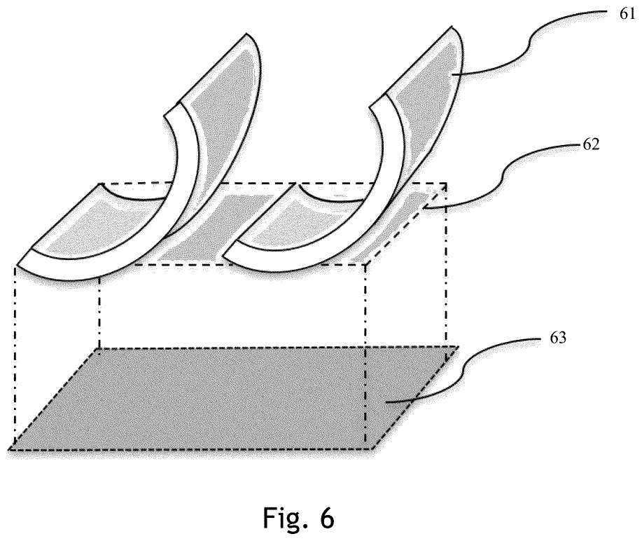

Reference is now made to FIG. 5, schematically illustrating a “tandem” selective spectral absorbance and transmittance solar cell. In the figure, the following elements are numbered as follows: direct sunlight radiation (51); a selective spectral absorbance and transmittance photovoltaic panel (52); selected light wavelength and intensity (53); plantation or crops (54); a DC/AC convertor (55); reflected IR (56); an electric pole (57). This “tandem” system comprises, inter alia, a plurality of n layers of absorbing materials, n is integer being equal or greater than 1, e.g., 2, 6, or 20, whose total transmittance is tailored to match plants' required absorption (light intensity vs wavelength) according to one embodiment of the present invention. At least one first elevated structure is carrying a photovoltaic cell positioned above the ground where vegetation is grown in a natural habitat comprising insects etc. Sun radiates electromagnetic spectra, some is utilized by the selective spectral absorbance and transmittance photovoltaic cell to produce energy, and some, e.g., spectra between the blue, green, and red (i.e., between about 400 to about 800 nm) utilizes for agricultural and urban purposes. In one embodiment of the invention, photovoltaic cell further comprises mechanically separate selective spectral absorbance and transmittance thin film solar cells, whose electrical contacts are connected outside the cells' active area, monolithically integrated, i.e. grown or composed together on one substrate being electrically and mechanically connected within the solar cells (e.g. with transparent conducting oxide layers); and both (i) and (ii)—parts are mechanically separate and parts are monolithically integrated. The photovoltaic (solar) cell absorb light in different wavelengths is tuned by using different semi conducting quantum-dots and/or different wavelength-tunable perovskite-based absorption layers. Cell further transmittance in different wavelength is determined by one or more members of a group consisting of (a) type of layers used, absorbing different wavelengths; (b) concentration of absorption centers (which affects the transmittance of light in the wavelength region absorbed by the absorption centers); (c) thickness of the wavelength-specific active layer in the cell (determining the amount of light absorbed/transmitted vs other layers in the solar cell.

Reference is now made to FIG. 6, schematically illustrating in an out-of-scale manner use of a suspended (elevated) agriphotovoltaic “tandem” selective spectral absorbance and transmittance solar cell system and modules thereof (61), having a base area A_{Tandem} (62). System 61 covers a portion of lower surface (marked green) having an area A_{Surface} (63) wherein A_{Tandem} (62)≥0.95 A_{Surface} (63). In other words, the agriphotovoltaic system covers at least 95% of the field below, and at the same time, enables either or both land farming and aquaculture.

It is in the scope of the invention wherein the elevated structure cover most of the area of the lower surface. Hence, according to one embodiment of the invention, the elevated structure covers up to about 51% of the lower surface. According to another embodiment of the invention, the elevated structure covers up to about 75% of the lower surface. According to another embodiment of the invention, the elevated structure covers up to about 95% of the lower surface. According to another embodiment of the invention, the elevated structure covers more than 95% of the lower surface.

It is in the scope of the invention provides the elevated structures useful for allowing both (a) rain drainage and (b) moisture evaporation.

It is also in the scope of the invention wherein at least one first elevated structure is located at a first height; and at least one second elevated structure is located at a second (higher) height. The at least one second (highest) structure cover at least one first portion of the at least one first (respectively lower) elevated structure, and both covers at least one second portion of the land (i.e., lowest surface).

It is also in the scope of the invention wherein a stack array comprises a plurality of elevated structures and a plurality of low surfaces is provided. Hence a higher-most elevated structure of a first type of photovoltaic cell or solar system harvest sun's at least one first energy spectrum. Under this is located a first agricultural producing system, e.g., aquaculture in transparent container.

Under this located a lowermost elevated structure of a second type of photovoltaic cell or solar system harvest sun's at least one second energy spectrum. Under this is located a second agricultural producing system, e.g., growing field crops.

New standard for combined usage for both agriculture and photovoltaic While ministries of agriculture are limiting the agrivoltaic land usage, ministries of energy are strongly supporting such a usage. The present invention hence discloses means and methods for a full photovoltaic usage, without any limitation to agriculture usage.

In one set of embodiments of the present invention, various compositions of PS, all of which are selective spectral absorbance and transmittance and thus suitable for use in agriculture, are disclosed. In yet another set of embodiments of the present invention, methods for making PS and QD for selective absorbance and transmittance, multi layers structure, are disclosed.

Various compositions of PS and QD of specific wavelengths, sizes and compositions are disclosed below: Lead containing perovskite have power conversion efficiency (PCE) above 25% in lab, poor lifetime (<2,000 hours) and strong impact on environment due to potential release of lead in a soluble form. Efforts have been made to fix these environmental challenges by looking for alternative element to Lead. One approach taken was to prevent the release of Lead degraded compounds by chemical sequestration. Another approach taken is improving the sealing of the module (mechanical improvement).

One aspect of the invention is hence the use of organometal halide perovskite with enhanced optical absorption in the red/IR range. CH₃NH₃PbX₃ (X is a halogen atom) where Pb is replicable. Characteristic absorption peaks in perovskite are being tailored to most wavelengths of the visible spectrum by adjusting the metal atom (Ge, Sn, and Pb), halogen (Cl, Br, and I) and/or inorganic sheet thickness. Typical perovskite CH₃NH₃PbI₃ exhibits a steep absorption onset at 825 nm (1.5 eV) with a large absorbance coefficient of about 5·10⁵ cm⁻¹. Pb perovskites composed of (CH₃NH₃⁺) or (HC(NH₂)₂⁺ cations and iodide (anion) emit between 700 and 800 nm while the emission of similar Sn perovskites lies within 850-1000 nm, covering a broad region of the near-IR spectrum (photoluminescence).

Another aspect of the invention is use lead free organometal halide perovskite: Pb is replicable by Sn, Bi, Ge, Sb and Cu. It is disclosed herein that improving lifetime is utilizable by adding spacers in the crystal lattice: phenyl ethyl ammonium chloride (PEACl). Lead free organometal halide perovskite is utilizable with a bandgap of below 1.48 eV. Lead Free perovskite utilizable for agrivoltaic solar cell is (CH₃NH₃)₃Bi₂I₉, Cs₂SnI₆, methylammonium tin iodide (MASnI₃), formamidinium tin iodide (FASnI₃), cesium tin iodide (CsSnI₃), bandgaps around 1.2-1.4 eV for lead-based perovskite, bandgaps of around 1.1 to 2.5 eV for lead free.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed:

1. A suspended solar cell system for use in agrophotovoltaic culture of plants, wherein said solar cell system comprising a plurality of n layers of absorbing materials, n is integer being equal or greater than 1, whose total transmittance is tailored to match plants' required absorption characterized by light intensity and wavelength required by said plants; further comprising mechanically separate semi-transparent thin film solar cells, whose electrical contacts are connected outside the cells' active area, monolithically integrated; wherein said solar cell light absorption in different wavelengths is tuned by using different semiconducting quantum-dots and/or different wavelength-tunable perovskite-based absorption layers; wherein said solar cell transmittance in different wavelength is determined by one or more members of a group consisting of (a) type of layers used, absorbing different wavelengths; (b) concentration of absorption centers which affects the transmittance of light in the wavelength region absorbed by said absorption centers; and (c) thickness of the wavelength-specific active layer in the cell determining the amount of light absorbed/transmitted vs other layers in the solar cell.

2. The suspended solar system of claim 1, wherein at least one portion of said solar cell system is a “tandem” semi-transparent system whose total transmittance is tailored to match said plants' required absorption characterized by light intensity and wavelength required by said plants; the base-area of “tandem” semi-transparent system is ATandem; plants are culturable in an area ASurface below said a base-area ATandem; said ATandem≥f×ASurface; f ranges between 0.51 to 1.00.

3. The suspended solar cell system of claim 1, wherein absorptance/transmittance properties of the solar cell are tailored not to transmittance curve general to all plants, said curve also known as the McCree curve, and a “synthetic” solar spectrum, but to a specific type of plant, at a specific physical latitude, said latitude affecting sun orientation and light intensity.

4. The suspended solar cell system of claim 1, wherein materials comprising the solar cells are non-toxic to biological lifeforms, e.g., not containing heavy-metals, including those selected from a group consisting of lead, chrome, and Antimony.

5. The suspended solar cell system of claim 1, utilizable in agrophotovoltaic culture of plants, wherein a use of said suspended solar cell system comprising steps of providing a “tandem” semi-transparent system whose total transmittance is tailored to match said plants' required absorption characterized by light intensity and wavelength required by said plants; providing said system with a base-area A_{Tandem}; and culturing said plants in an area A_{Surface} below said a base-area A_{Tandem}; said A_{Tandem}≥f×A_{Surface}; f ranges between 0.51 to 1.00.

6. The suspended solar cell system of claim 5, wherein absorptance/transmittance properties of the solar cell are tailored not to transmittance curve general to all plants, said curve also known as the McCree curve, and a “synthetic” solar spectrum, but to a specific type of plant, at a specific physical latitude, said latitude affecting sun orientation and light intensity.

7. The suspended solar cell system of claim 5, wherein materials comprising the solar cells are non-toxic to biological lifeforms, e.g., not containing heavy-metals, including those selected from a group consisting of lead, chrome, and Antimony.
